(19) United States
(12) Patent Application Publication
(10) Pub. No.: US 2014/0017833 A1
(43) Pub. Date: Jan. 16, 2014

(54) MANUFACTURING METHOD FOR LIQUID CRYSTAL DISPLAY DEVICE

(71) Applicant: Panasonic Liquid Crystal Display Co., Ltd., Himeji-shi (JP)

(72) Inventors: Ryuji MATSUMOTO, Hyogo (JP); Shigekazu HORINO, Osaka (JP); Kouji HARADA, Osaka (JP)

(21) Appl. No.: 13/938,866

(22) Filed: Jul. 10, 2013

(30) Foreign Application Priority Data
Jul. 11, 2012 (JP) 2012-155955

(51) Int. Cl. H01L 33/48

(52) U.S. Cl. CPC H01L 33/48
USPC 438/30

(57) ABSTRACT

A manufacturing method for a liquid crystal display device according to this application is a manufacturing method for a liquid crystal display device having a transparent substrate (2), a TFT (5) formed on the transparent substrate (2), a lower insulating film (4) covering the TFT (5), an organic insulating film (6) covering the lower insulating film (4), a common electrode (7) formed on the organic insulating film (6), an upper insulating film (8) covering the common electrode (7), and a pixel electrode (9) formed on the upper insulating film (8). Annealing process is performed after formation of the organic insulating film (6) before formation of the upper insulating film (8).

### CROSS-REFERENCE TO RELATED APPLICATION

The present application claims priority from Japanese application JP2012-155955 filed on Jul. 11, 2012, the entire content of which is hereby incorporated by reference into this application.

### TECHNICAL FIELD

This application relates to a manufacturing method for a liquid crystal display device having an organic insulating film.

### BACKGROUND

Japanese Patent Laid-open Publication No. 2011-059314 discloses a liquid crystal display device having a relatively thick flat-surfaced organic insulating film made of organic material, such as acrylic resin or the like, formed on an inorganic insulating film (a lower insulating film) covering a thin film transistor.

Such an organic insulating film is covered by an inorganic insulating film (an upper insulating film), and a common electrode is formed between an organic insulating film and the upper insulating film, while a pixel electrode is formed on the upper insulating film. The common electrode and the pixel electrode are made of indium-tin oxide (ITO), which is first deposited in a non-crystallized state, and then heated for polycrystallization.

Note here that an organic insulating film may generate gas or is deformed upon exposure to high temperature. Accordingly, when a common electrode, an upper insulating film, and a pixel electrode are formed one on the other on an organic insulating film, and thereafter entirely heated for polycrystallization of ITO, stress may be applied to the respective layers formed on the organic insulating film due to the gas generated by and deformation of the organic insulating film, and the respective layers may be separated from each other.

In view of the above, according to Japanese Patent Laid-open Publication No. 2011-059314 mentioned above, a formation region for the upper insulating film is limited to only on the organic insulating film to avoid adhesion between the upper insulating film and the lower insulating film to release a stress caused on the organic insulating film to thereby prevent layer separation. However, when a formation region of the upper layer insulating film is limited to on the organic insulating film, it may rise a problem that refinement of a pattern of a hole or the like is difficult to be achieved.

This application has been conceived in view of the above described situation, and a main object thereof is to provide a manufacturing method for a liquid crystal display device capable of preventing layer separation without limiting a formation region of an upper insulating film.

### SUMMARY

In order to achieve the above described object, according to an embodiment of this application, there is provided a manufacturing method for a liquid crystal display device including a transparent substrate, a thin film transistor formed on the transparent substrate, a lower insulating film covering the thin film transistor, an organic insulating film including organic material, for covering the lower insulating film, a first electrode formed on the organic insulating film, an upper insulating film covering the first electrode, and a second electrode formed on the upper insulating film, the manufacturing method includes performing annealing process after formation of the organic insulating film before formation of the upper insulating film.

In an embodiment of this application, the first electrode may be made using a transparent conductive film made of oxide, and the annealing process may be performed after formation of the transparent conductive film that makes the first electrode on the organic insulating film.

In an embodiment of this application, the liquid crystal display device may further include a line made of metal material and connected to the first electrode, and the annealing process may be performed in vacuum or inert gas atmosphere after formation of the line on the transparent conductive film.

In an embodiment of this application, the annealing process and formation of the upper insulating film may be performed in a same reaction chamber.

In an embodiment of this application, a minimum thickness of the organic insulating film may be larger than a thickness of the lower insulating film.

In an embodiment of this application, the organic insulating film may be formed by coating liquid organic material on the lower insulating film and then curing.

In an embodiment of this application, the first electrode may be a common electrode, and the second electrode may be a pixel electrode.

According to this application, as degassing and deformation of an organic insulating film is performed due to annealing process before an organic insulating film is covered by an upper insulating film, layer separation can be prevented without limiting a formation region of the upper insulating film.

### BRIEF DESCRIPTION OF THE DRAWINGS

FIG. 1 schematically shows an example structure of a TFT substrate of a liquid crystal display device;

FIG. 2 shows an embodiment of a manufacturing method for a liquid crystal display device according to this application;

FIG. 3 is a continuation of FIG. 2;

FIG. 4 is a continuation of FIG. 3;

FIG. 5 is a continuation of FIG. 4;

FIG. 6 is a continuation of FIG. 5;

FIG. 7 is a continuation of FIG. 6; and

FIG. 8 is a continuation of FIG. 7.

### DETAILED DESCRIPTION

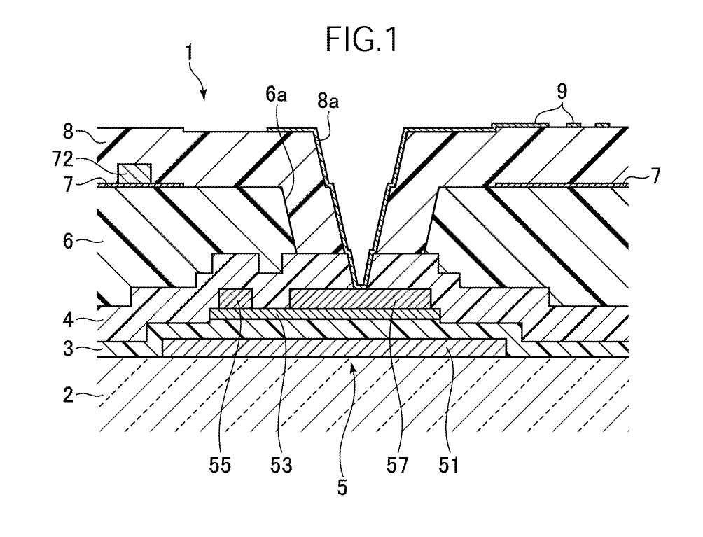

An embodiment of a manufacturing method for a liquid crystal display device according to this application will be described with reference to the accompanying drawings. Initially, a liquid crystal display device that is manufactured in this embodiment will be described. FIG. 1 schematically shows an example structure of a TFT substrate 1 of a liquid crystal display device. In FIG. 1, an area near a thin film transistor (TFT) 5 included in each of the pixels of the TFT substrate 1 is shown enlarged.

On the TFT substrate 1, a TFT 5 is formed on a transparent substrate 2 made of non-alkali glass or the like. The TFT 5 includes a gate electrode 51, a semiconductor layer 53, a source electrode 55, and a drain electrode 57. A semiconductor layer 53 is formed on the gate electrode 51, and a gate insulating film 3 is formed between the gate electrode 51 and the semiconductor layer 53. A source electrode 55 and a drain electrode 57 are formed on the semiconductor layer 53.

The TFT 5 and the gate insulating film 3 are covered by a lower insulating film 4. The lower insulating film 4 is covered by an organic insulating film 6. The organic insulating film 6 is formed relatively thick and has a flat surface. A common electrode 7 is formed on the organic insulating film 6, and connected to a common line 72. The common electrode 7 and the organic insulating film 6 are covered by an upper insulating film 8. A pixel electrode 9 is formed on the upper insulating film 8. Note that the positional relationship in the up-down direction of the common electrode 7 and the pixel electrode 9 may be reversed.

A hole 6a is formed in the organic insulating film 6 in a position above the drain electrode 57 such that the lower insulating film 4 is exposed at the bottom thereof. The upper insulating film 8 fills the hole 6a, and contacts the lower insulating film 4. A hole 8a is formed in the lower insulating film 4 and the upper insulating film 8, through inside the hole 6a of the organic insulating film 6, such that the drain electrode 57 is exposed at the bottom thereof. The pixel electrode 9 is formed in the hole 8a to be connected to the drain electrode 57.

The gate electrode 51, source electrode 55, and drain electrode 57 of the TFT 5 are made of metal such as Cu, Al, or the like. The semiconductor layer 53 is made of semiconductor such as amorphous Si or the like. The gate insulating film 3, the lower insulating film 4, and the upper insulating film 8 are made of transparent inorganic insulating material, such as SiN or the like. Organic material that constitutes the organic insulating film 6 will be described later. The common electrode 7 and the pixel electrode 9 are transparent conductive films made of oxide, such as indium-tin oxide (ITO) or the like.

On the TFT substrate 1, an alignment film (not shown) is formed above the upper insulating film 8 and the pixel electrode 9, and a polarizer plate (not shown) is formed below the transparent substrate 2. A liquid crystal layer is sandwiched by the TFT substrate 1 and a color filter (CF) substrate (not shown), whereby a liquid crystal panel is formed. When a driving circuit is mounted on such a liquid crystal panel, a liquid crystal display device is formed.

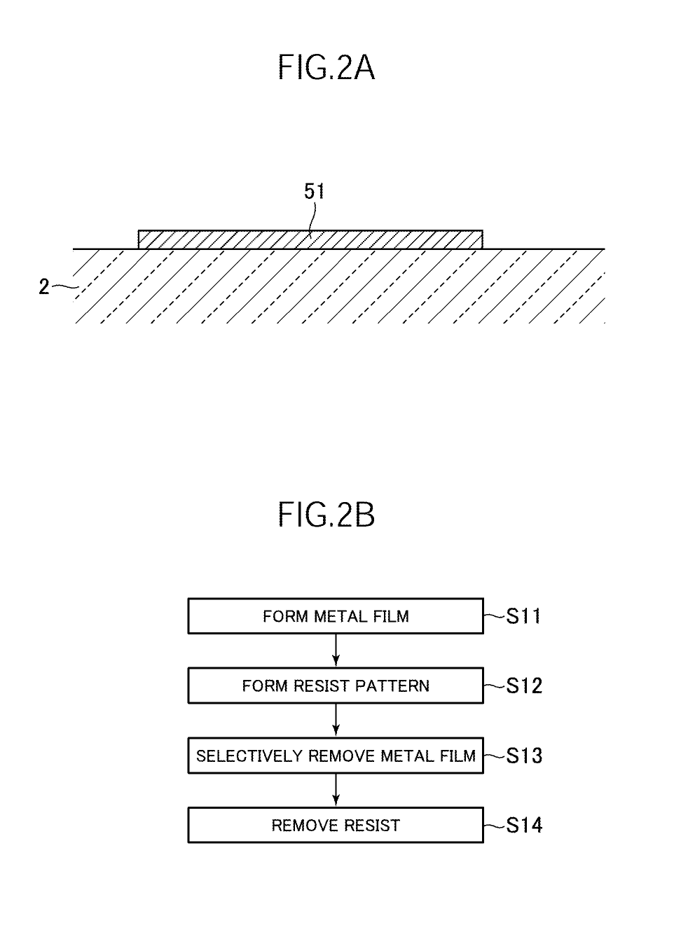

FIGS. 2 to 8 show an embodiment of a manufacturing method for a liquid crystal display device according to this application. A cross sectional view A in these diagrams shows a state at completion of thin film processing at a photolithography step and through etching, with a photoresist removed, while a flowchart B shows major steps followed before achievement of such a state.

Note here that a photolithography step refers to a step including a series of processing for forming a resist pattern, including coating of photoresist, selective exposure using a photo mask, and development, with detailed description thereof omitted below.

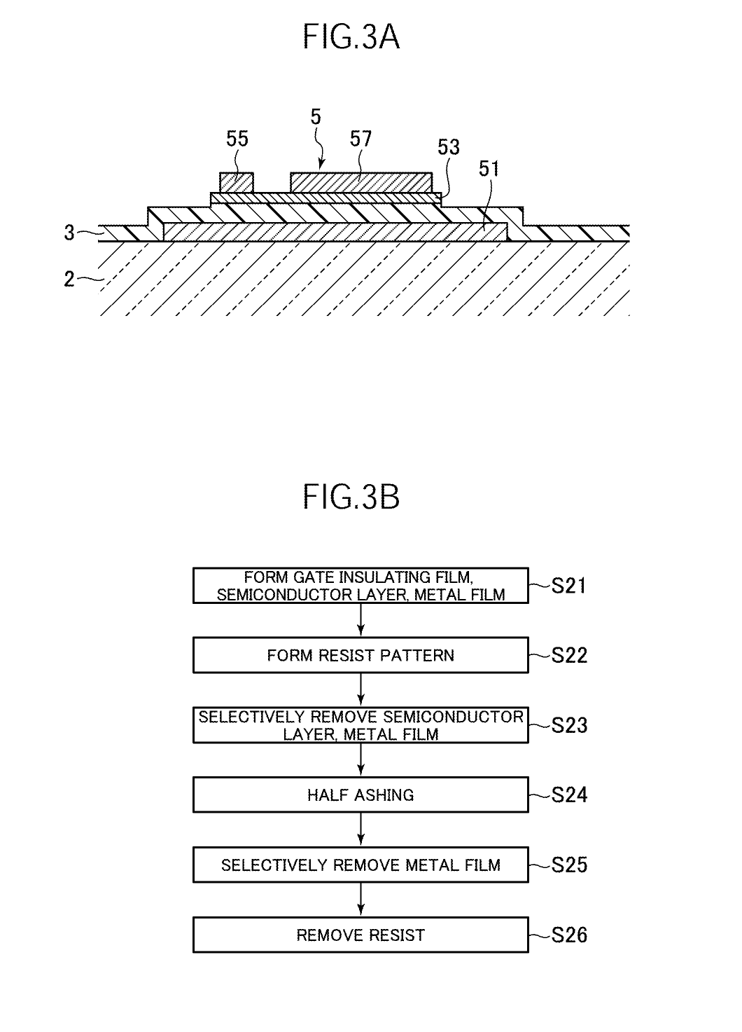

At the steps shown in FIG. 2, the gate electrode 51 is formed. Specifically, initially, a metal film made of metal such as Cu, Al, and so forth, is formed on the transparent substrate 2 through sputtering (S11). Then, a resist pattern is formed on the metal film (S12), and the metal film is selectively etched (S13). Thereafter, the photoresist is removed (S14). With the above, the gate electrode 51 is formed on the transparent substrate 2. At the steps shown in FIG. 3, the gate insulating film 3, the semiconductor layer 53, the source electrode 55, and the drain electrode 57 are formed. Specifically, ammonia gas, silane gas, and nitrogen gas are introduced into a reaction chamber of a CVD device to form a gate insulating film 3 made of SiNx. Then, silane gas and hydrogen gas are introduced to form a semiconductor layer made of amorphous Si, and a metal film made of metal such as Cu, Al, and so forth is thereafter formed through sputtering (S21).

Thereafter, a resist pattern using a halftone mask is formed on the metal film (S22). Note here that a photoresist is formed relatively thick in a region where the source electrode 55 and the drain electrode 57 are formed, and a photoresist is formed relatively thin in a region between the source electrode 55 and the drain electrode 57. No photoresist is formed in a region free from the semiconductor layer 53. Then, the metal film and the semiconductor layer are selectively etched (S23). Then, a part of the photoresist formed thin is removed by half asking (S24), and the metal film in the thereby exposed region is etched (S25). Thereafter, the photoresist is removed (S26). With the above, the gate insulating film 3, the semiconductor layer 53, the source electrode 55, and the drain electrode 57 are formed, whereby the TFT 5 is completed.

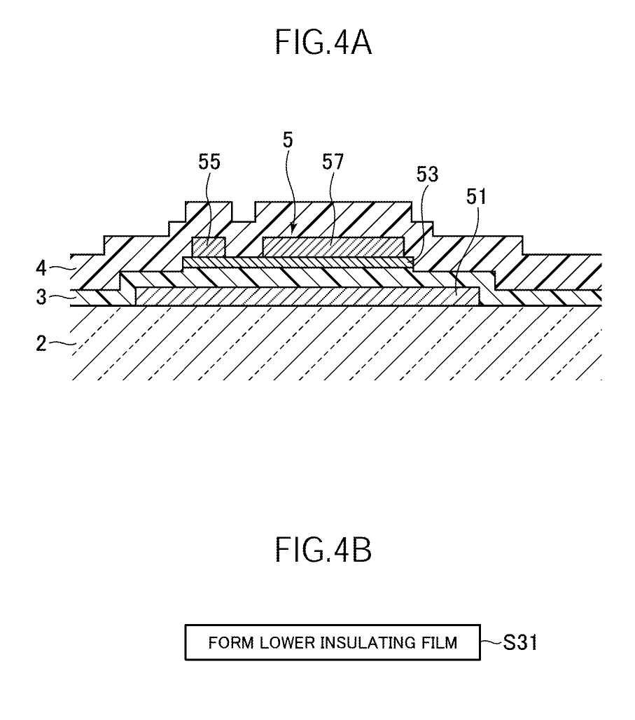

At the steps shown in FIG. 4, the lower insulating film 4 is formed. Specifically, ammonia gas, silane gas, and nitrogen gas are introduced into the reaction chamber of the CVD device to form the lower insulating film 4 made of SiNx on the TFT 5 and the gate insulating film 3 (S31).

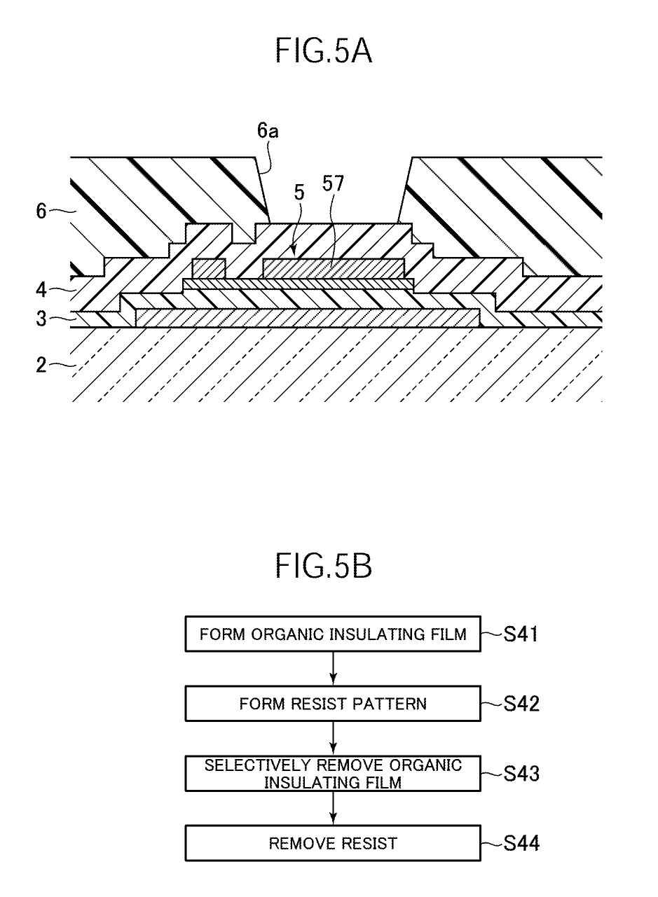

At the steps shown in FIG. 5, the organic insulating film 6 is formed. Specifically, liquid organic material is coated on the lower insulating film 4 and cured, whereby the organic insulating film 6 is formed (S41). Acrylic resin, for example, maybe available as organic material for forming the organic insulating film 6, though this is not limiting, and silicone resin, epoxy resin, polyimide resin, and so forth, are also usable. The organic insulating film 6 may include inorganic filling member, such as silica, or the like. Such organic material is dissolved in an organic solvent, then coated onto the lower insulating film 4, and thereafter heated to temperature close to the melting temperature to be thereby cured. The curing temperature is, for example, lower than that of organic material by 10 to 20° C. (for the melting temperature at 260° C., curing temperature is about 240 to 250° C.). The organic insulating film 6 formed as described above is a planarization film having a flat surface, of which minimum thickness is larger than the lower insulating film 4 and the upper insulating film 8.

Thereafter, a resist pattern is formed on the organic insulating film 6 (S42). The organic insulating film 6 is selectively etched (S43). In the above, a hole 6a is formed in a part of the organic insulating film 6 above the drain electrode 57 such that the lower insulating film 4 is exposed at the bottom thereof. Thereafter, the photoresist is removed (S44). With the above, the organic insulating film 6 is formed in the lower insulating film 4, and the hole 6a is formed in the organic insulating film 6.

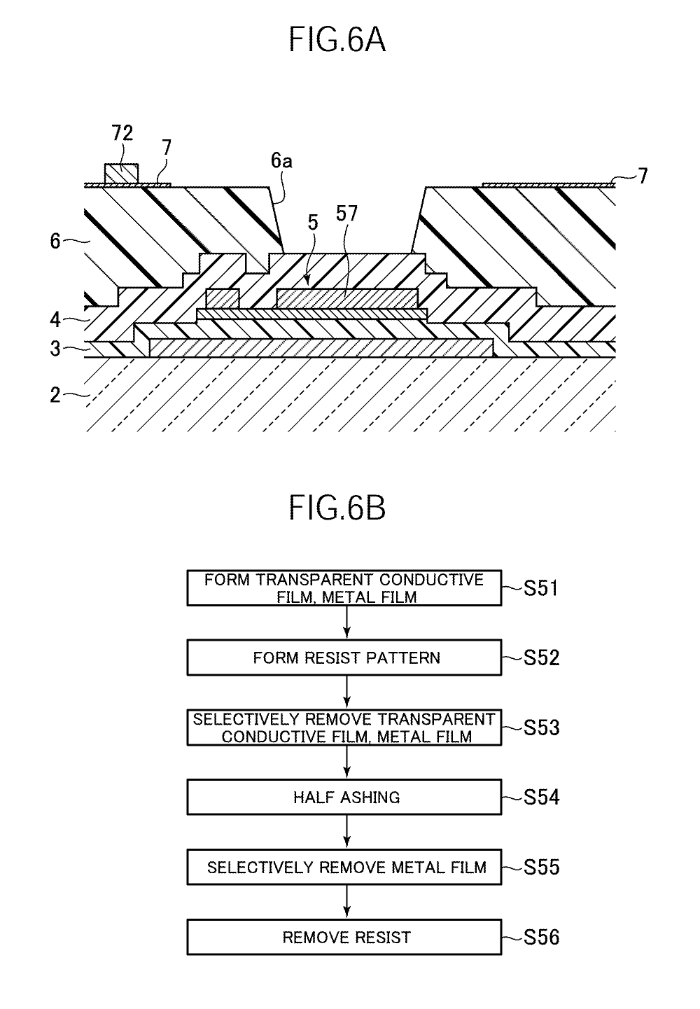

At the steps shown in FIG. 6 the common electrode 7 and the common line 72 are formed. Specifically, a transparent conductive film made of oxide, such as ITO, or the like, is formed on the organic insulating film 6 through sputtering, and a metal film made of metal, such as Cu, Al, or the like is further formed through sputtering (S51). The formation temperature of the transparent conductive film and the metal film is lower than the curing temperature of the organic insulating film 6, being, for example, about 90 to 100° C. Thereafter, a resist pattern using a halftone mask is formed on the metal film (S52). Note here that a photoresist is formed relatively thick in a region where the common line 72 is formed, and relatively thin in a region where the common electrode 7 alone is formed, and no photoresist is formed in a region without the common electrode 7. Then, the metal film and the transparent conductive film are selectively etched (S53). Further, a part of the photoresist that is formed thin is removed through half asking (S54), and the metal film in the thereby exposed region is etched (S55). Thereafter, the photoresist is removed (S56). With the above, the common electrode 7 and the common line 72 are formed.

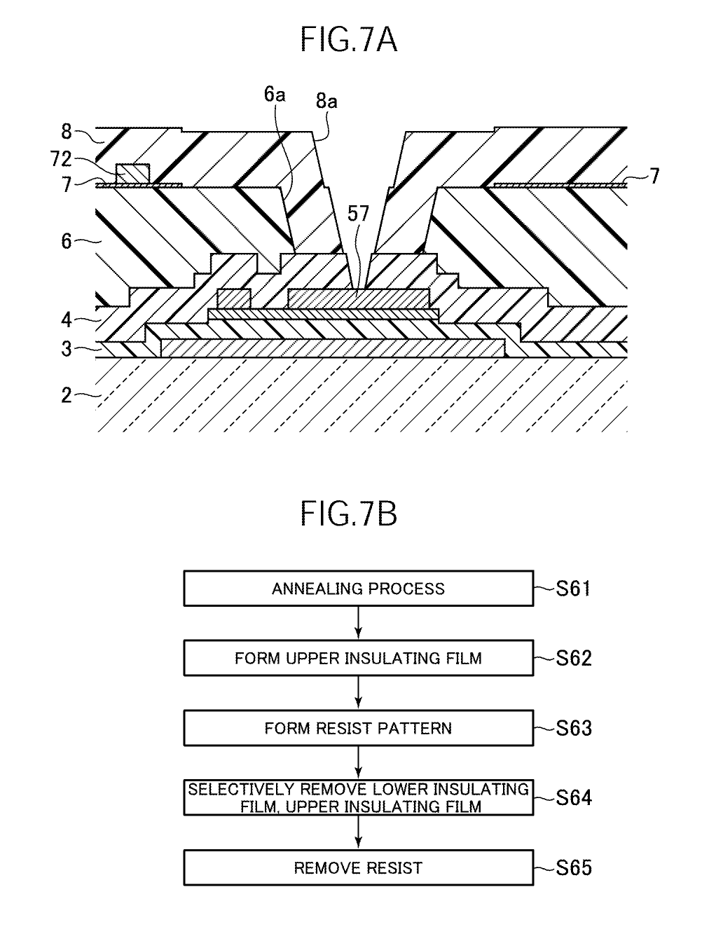

At the step shown in FIG. 7, where the upper insulating film 8 is formed, annealing process is performed before the formation (S61). Annealing process is performed in vacuum atmosphere in the reaction chamber of the CVD device at temperature close to the melting temperature of the organic insulating film 6. The temperature for annealing process is, for example, lower than the melting temperature of organic material by about 10 to 20° C., (for the melting temperature at 260° C., the curing temperature is about 240 to 250° C.). Further, a period of time for annealing process is, for example, about two to four minutes. With this annealing process, degassing and deformation of the organic insulating film 6 is performed before the organic insulating film 6 is covered by the upper insulating film 8. Accordingly, layer separation can be prevented even when the entirety is heated after the organic insulating film 6 is covered by the upper insulating film 8. Further, as annealing process is performed after formation of the common electrode 7, it is possible to achieve polycrystalization of the common electrode 7, together with degassing and deformation of the organic insulating film 6. Further, as annealing process is performed in vacuum atmosphere, it is possible to prevent oxidation of the common line 72 made of metal material, and to promote degassing with the organic insulating film 6. Note that annealing process may be performed in inert gas atmosphere. Further, as annealing process is performed in the same reaction chamber as that which is used for formation of the upper insulating film 8, it is possible to achieve prompt and simplified manufacturing process.

Thereafter, ammonia gas, silane gas, and nitrogen gas are introduced into the reaction chamber of the CVD device to form an upper insulating film 8 made of SiNx on the organic insulating film 6 (S62). In the above, the upper insulating film 8 fills the hole 6a formed in the organic insulating film 6 and contacts the lower insulating film 4 exposed at the bottom of the hole 6a. Then, a resist pattern is formed on the upper insulating film 8 (S63); the upper insulating film 8 is selectively etched (S64). In the above, a hole 8a is formed in the lower insulating film 4 and the upper insulating film 8, through inside the hole 6a of the organic insulating film 6, such that the drain electrode 57 is exposed at the bottom thereof. Thereafter, the photoresist is removed (S65).

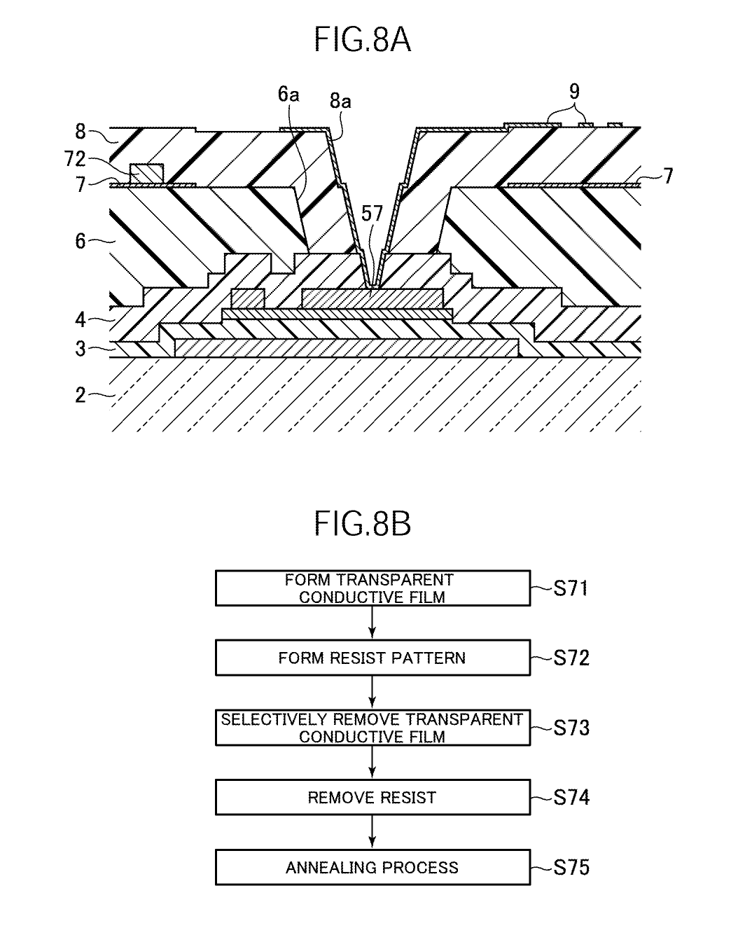

At the step shown in FIG. 8, the pixel electrode 9 is formed. Specifically, a transparent conductive film made of oxide, such as ITO or the like, is formed on the upper insulating film 8 through sputtering (S71). Thereafter, a resist pattern is formed on the transparent conductive film (S72), and the transparent conductive film is selectively etched (S73). Thereafter, the photoresist is removed (S74). Further, annealing process is performed to polycrystalize the transparent conductive film in a non-crystallized state (S75). Note that as degassing and deformation of the organic insulating film 6 and polycrystallization of the common electrode 7 are already on progress in the former annealing process (S61), layer separation seldom occurs in this annealing process (S75). With the above, the pixel electrode 9 is formed on the upper insulating film 8, and in the hole 8a to be connected to the drain electrode 57 exposed at the bottom of the hole 8a.

Thereafter, an alignment film (not shown) is formed above the upper insulating film 8 and the pixel electrode 9, and a polarizer plate (not shown) is formed below the transparent substrate 2, whereby the TFT substrate 1 is completed. A liquid crystal layer is held between the TFT substrate 1 and a CF substrate (not shown), whereby a crystal liquid panel is completed. When a driving circuit is mounted in such a crystal panel, a liquid crystal display device is completed.

Although an embodiment of this application has been described in the above, this application is not limited to the above described embodiment, and various modified embodiments are possible for a person skilled in the art.

In the above-described embodiment, annealing process (S61) is performed after the step of forming the common electrode 7 and the common line 72 on the organic insulating film 6 (S51 to S56). This, however, is not limiting, and annealing process may be performed before the step of forming the common electrode 7 and the common line 72 on the organic insulating film 6 (S51 to S56). With the above, as the common electrode 7 is formed on the organic insulating film 6 that is already subjected to degassing and deformation in annealing process, it is possible to prevent layer separation of the organic insulating film 6 and the common electrode 7.

While there have been described what are at present considered to be certain embodiments of the invention, it will be understood that various modifications may be made thereto, and it is intended that the appended claims coverall such modifications as fall within the true spirit and scope of the invention.

What is claimed is:

1. A manufacturing method for a liquid crystal display device including
a transparent substrate,
a thin film transistor formed on the transparent substrate,
a lower insulating film covering the thin film transistor,
an organic insulating film including organic material, for covering the lower insulating film,
a first electrode formed on the organic insulating film,
an upper insulating film covering the first electrode, and
a second electrode formed on the upper insulating film, the manufacturing method comprises:
performing annealing process after formation of the organic insulating film before formation of the upper insulating film.

2. The manufacturing method for a liquid crystal display device according to claim 1, wherein
the first electrode is made using a transparent conductive film made of oxide, and
the annealing process is performed after formation of the transparent conductive film that makes the first electrode on the organic insulating film.

3. The manufacturing method for a liquid crystal display device according to claim 2, wherein
the liquid crystal display device further includes a line made of metal material and connected to the first electrode, and
the annealing process is performed in vacuum or inert gas atmosphere after formation of the line on the transparent conductive film.

4. The manufacturing method for a liquid crystal display device according to claim 1, wherein the annealing process and formation of the upper insulating film are performed in a same reaction chamber.

5. The manufacturing method for a liquid crystal display device according to claim 1, wherein a minimum thickness of the organic insulating film is larger than a thickness of the lower insulating film.

6. The manufacturing method for a liquid crystal display device according to claim 1, wherein the organic insulating film is formed by coating liquid organic material on the lower insulating film and then curing.

7. The manufacturing method for a liquid crystal display device according to claim 1, wherein the first electrode is a common electrode, and the second electrode is a pixel electrode.
